(19) United States
(12) Patent Application Publication
(10) Pub. No.: US 2012/0174582 A1
(43) Pub. Date: Jul. 12, 2012

(54) HYBRID SOLAR ENERGY COLLECTOR, AND SOLAR POWER PLANT INCLUDING AT LEAST ONE SUCH COLLECTOR

(75) Inventor: Mehdi Moussavi, Paris (FR)

(73) Assignee: AREVA, Paris (FR)

(21) Appl. No.: 13/388,621

(22) PCT Filed: Jul. 30, 2010
(86) PCT No.: PCT/FR2010/051630

§ 371 Date: Feb. 13, 2012

(30) Foreign Application Priority Data
Aug. 3, 2009 (FR) 09 55460

(51) Int. Cl. F03G 6/00; H01L 31/058

(52) U.S. Cl. 60/641.8; 136/248

(57) ABSTRACT

A collector is provided including at least one photovoltaic cell for converting solar energy into electric energy, and at least one heat sink for converting solar energy into heat energy by heating a fluid, arranged so as to receive solar energy through the photovoltaic cell. The photovoltaic cell includes a plurality of vertically adjacent semiconductor junctions having different forbidden energy bands, each semiconductor junction having a forbidden energy band of greater than or equal to 1.2 eV, in particular greater than or equal to 1.4 eV.

### BACKGROUND

The present invention relates to the field of hybrid solar energy converters.

A “hybrid” solar energy collector is named as such because it converts the solar energy it receives into different forms of energy, in particular electric energy and heat energy.

It is possible to provide a hybrid solar energy collector of the type comprising at least one photovoltaic cell for the conversion of solar energy into electric energy and at least one heat sink for the conversion of solar energy into heat energy by heating a fluid, arranged so as to receive the solar energy through the photovoltaic cell.

Solar energy not converted into electric energy by the photovoltaic cells heats the fluid circulating in the conduit and is thus converted into heat energy.

With the aim of improving the of converted solar energy/received solar energy output of the photovoltaic cells, photovoltaic cells have been considered with multiple vertically adjacent semiconductor junctions having forbidden energy bands (or “bandgap”) of different widths, so that they convert the solar energy into electric energy in the different light wavelength ranges, so as to cover the widest spectral band of the solar spectrum.

Nevertheless, these photovoltaic cells are expensive to manufacture.

WO2004/099682 discloses an individual solar energy collector comprising a photovoltaic cell for converting solar energy into electric energy and a cooling device of the photovoltaic cell, making it possible to recover the heat from the photovoltaic cell.

Nevertheless, the cooling device is provided to recover the heat from the photovoltaic cell through heat conduction between the cooling device and the photovoltaic cell. It does not make it possible to effectively convert solar energy into heat energy, in particular when the considered applications are of the steam turbine type coupled with a generator with working fluid temperatures much higher than those considered in WO2004/099682.

The photovoltaic cell is provided to be of the “high-efficiency” type with a triple junction comprising three vertically adjacent semiconductor junctions to convert solar energy over a wide light frequency range.

InGaP/GaAs tandem photovoltaic cells are described in the publications “High Efficiency InGaP solar cells for InGap/GaAs tandem cells applications,” world conference on photovoltaic energy, Waikoloa, HI, USA, Dec. 5-9, 1994, pages 1729-1732 and “GaInP single junction and GaInP/GaAs two junction thin-film solar cells structures by epitaxial lift-off,” Solar energy materials and solar cells, vol. 50, no. 1-4, January 1998, pages 229-235.

### SUMMARY OF THE INVENTION

One aim of the invention is to provide a hybrid solar energy collector having satisfactory output (electric+heat) while preserving a reasonable production cost.

Another aim of the invention is to provide a hybrid solar energy collector making it possible to couple the heat portion to a steam turbine electric power station.

A hybrid solar energy collector is provided including a photovoltaic cell including several vertically adjacent semiconductor junctions having different forbidden energy band widths, each semiconductor junction having a forbidden energy band of width equal to or greater than 1.2 eV, in particular equal to or greater than 1.4 eV.

According to other embodiments, the solar energy collector comprises one or more of the following features, considered alone or according to all technically possible combinations:
the photovoltaic cell comprises at least one GaAs semiconductor layer;
the photovoltaic cell comprises at least one GaInP or GaInP2 semiconductor layer;
the semiconductor junctions of the photovoltaic cell are formed by fine semiconductor layers;
the semiconductor layers have a thickness comprised between 1 and 20 μm, in particular between 1 and 10 μm;
the semiconductor layers are formed on a substrate, in particular using a transfer or epitaxy method;
the substrate is made from a material chosen between glass or an infrared-transparent ceramic;
the solar energy collector comprises a concentrator for concentrating an incident solar beam to form a concentrated solar beam toward the photovoltaic cell and the heat sink; and
the concentration factor of the concentrator is comprised between 80 and 120, in particular approximately equal to 100.

Carefully choosing the materials for the photovoltaic cell, as well as optimizing the thicknesses thereof, makes it possible to preserve the greatest possible amount of infrared transparency for the conversion.

The invention also relates to an electricity-producing solar power plant comprising at least one solar energy collector as defined above.

The invention also relates to a power station comprising a circuit for the circulation of the coolant connected to the energy conversion device, a steam power station comprising at least one steam turbine, a circuit for the circulation of a working fluid connected to the steam power station, and at least one heat exchanger between the circulation circuit for the coolant and the circulation circuit for the working fluid.

### BRIEF SUMMARY OF THE DRAWINGS

The invention and the advantages thereof will be better understood upon reading the following description, provided solely as an example, and done in reference to the appended drawings, in which:

FIG. 1 is a diagrammatic side view of a hybrid solar energy collector according to the invention;

FIG. 2 is a diagrammatic cross-sectional view of a photovoltaic cell of the solar energy collector of FIG. 1;
FIG. 3 is an overall diagrammatic view of a solar power station comprising solar energy collectors according to FIG. 1;
FIG. 4 is a view similar to that of FIG. 1 illustrating a solar energy collector according to one alternative of the invention;
FIG. 5 is a diagrammatic perspective view of a heat sink and photovoltaic cells of the solar energy collector of FIG. 4,
FIGS. 6 and 7 are partial views of solar energy collectors according to alternatives of the invention.

### DETAILED DESCRIPTION

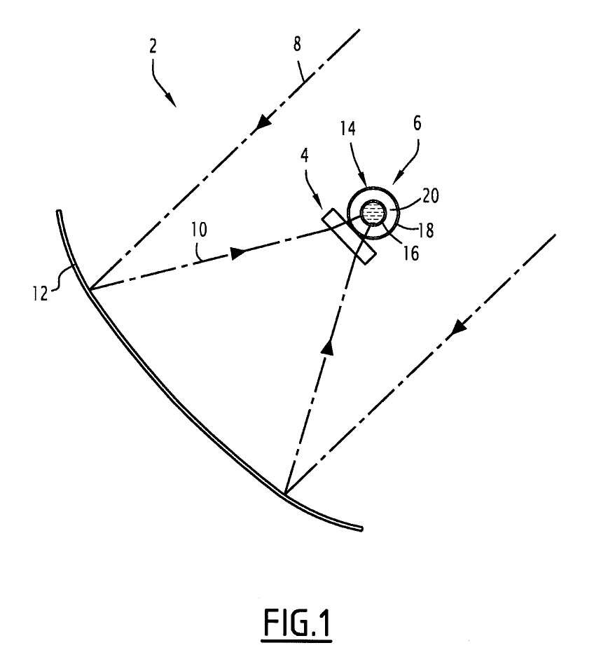

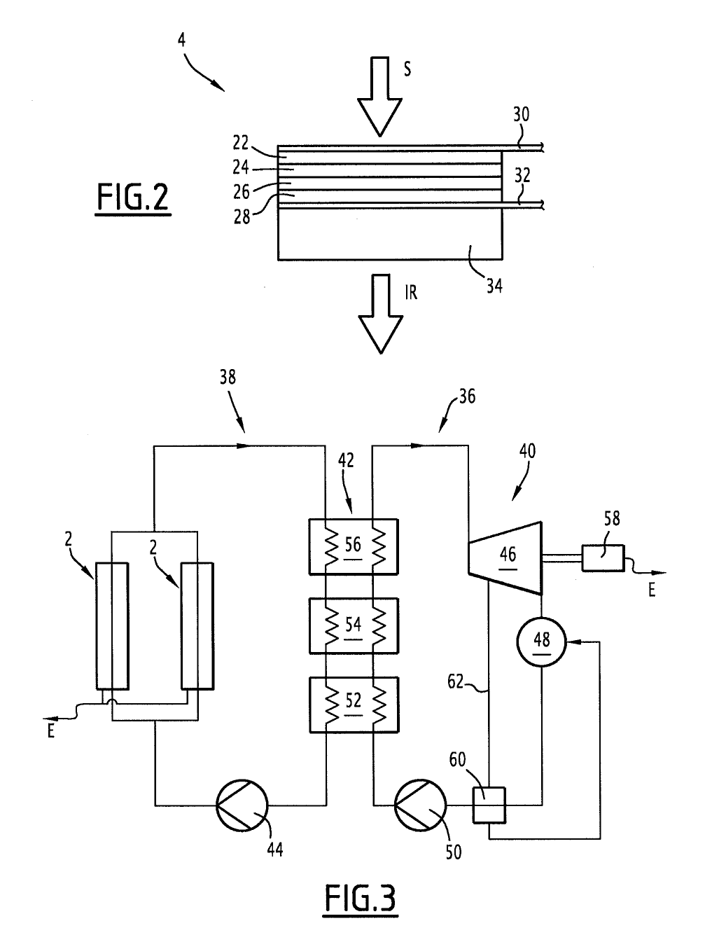

The hybrid solar energy collector 2 of FIG. 1 makes it possible to convert solar energy into electric energy and heat energy at the same time.

The collector 2 comprises at least one photovoltaic cell 4 for converting solar energy into electric energy and at least one heat sink 6 for converting solar energy into heat energy by heating a fluid, arranged so as to receive the solar energy through the photovoltaic cell 4.

The collector 2 is of the concentration type. It comprises a concentrator for concentrating an incident solar beam 8 into a concentrated solar beam 10 oriented toward an energy converter defined by the photovoltaic cell 4 and the heat sink 6.

In the illustrated example, the concentrator assumes the form of a cylindroparabolic mirror 12 oriented so as to direct the concentrated beam 10 toward the energy converter, preferably situated substantially at the focal point of the mirror 12.

In a known manner, the collector 2 can preferably be oriented so as to be moved with the sun and oriented toward the latter.

As shown in FIG. 1, the heat sink 6 assumes the form of a conduit 14 with a double wall and intermediate vacuum, comprising an inner tube 16 for the circulation of a fluid and an outer tube 18 surrounding the inner tube 16, an annular insulating space 20 being delimited between the inner 16 and outer 18 tubes. At least a partial vacuum is created in the annular space 20 so as to limit the outward heat losses.

Alternatively, the heat sink can be formed by a single steel tube and/or a bundle of steel tubes.

During operation, the concentrated light beam 10 is received by the photovoltaic cell 4, which converts part of the solar energy into electric energy. Part of the concentrated light beam 10 passes through the photovoltaic cell 4 and reaches the heat sink 6, which converts at least part of the solar energy it receives into thermal energy by heating the fluid circulating in the heat sink 6.

The fluid circulating in the heat sink 6 is in particular heated by the infrared rays (IR rays) passing through the photovoltaic cell 4 and the conduit 14.

As illustrated in FIG. 2, the photovoltaic cell 4 is a photovoltaic cell with multiple semiconductor junctions comprising several superimposed semiconductor junctions.

The semiconductor junctions have forbidden energy bands (band-gaps) of different widths.

A semiconductor junction converts the light rays whereof the photons are situated in an energy range greater than the width of the forbidden energy band of the semiconductor junction.

The energy of a photon is expressed in electronvolts (eV) and is substantially inversely proportional to the corresponding light wavelength, generally expressed in nanometers (nm).

In this way, a semiconductor junction converts the light rays into electricity in a wavelength range smaller than that corresponding to the width of its forbidden energy band, and does not convert the light rays in a wavelength range greater than that corresponding to the width of its forbidden energy band.

The semiconductor junctions have forbidden energy bands of different widths therefore converting the light rays into electric energy in different wavelength ranges. The association of semiconductor junctions having forbidden energy bands of different widths therefore allows a conversion of the light energy in an extended wavelength range.

According to one aspect of the invention, the semiconductor junctions of the photovoltaic cell 4 all have a forbidden energy band width equal to or greater than 1.2 eV, and in particular equal to or greater than 1.4 eV.

In this way, the semiconductor junctions do not convert the light rays with wavelengths equal to or greater than 1033 nm, in particular equal to or greater than 885 nm.

The semiconductor junctions therefore make it possible to limit the absorption of the IR rays situated in the wavelength range above 780 nm.

These IR rays passing through the photovoltaic cell 4 are received by the heat sink 6 (FIG. 1) and allow effective heating of the fluid circulating in the heat sink 6.

Instead of converting the solar rays into electric energy in the widest possible wavelength range, the invention therefore proposes to use the rays with higher wavelengths for conversion into electric energy and to use the rays with smaller wavelengths, in particular in the IR range, for conversion into heat energy, in which they are effective.

This distribution allows a satisfactory output, and makes it possible to obtain a simple and inexpensive photovoltaic cell.

Advantageously, the photovoltaic cell 4 is made up of semiconductor layers with a base of materials III-V comprising at least one compound from column III of Mendeleïev's table and at least one compound from group V from Mendeleïev's table. These materials are binary, ternary, quaternary, etc. as a function of the number of compounds from columns III and V.

Also advantageously, the photovoltaic cell 4 comprises at least one GaAs semiconductor layer and/or at least one GaInP or GaInP2 semiconductor layer, which are reasonably-priced materials making it possible to obtain semiconductor junctions with appropriate forbidden energy band widths.

In the illustrated example, the photovoltaic cell 4 is of the GaAs/GaInP double junction type and comprises a first GaAs junction formed by two GaAs semiconductor layers 22, 24 that are superimposed and doped differently (e.g. one n and the other p), and a second GaInP junction formed by two GaInP semiconductor layers 26, 28 that are superimposed and doped differently (e.g. one n and the other p).

Advantageously, the adjacent GaAs 24 and GaInP 26 semiconductor layers are connected so that they also form a GaAs/GaInP heterojunction.

The first GaAs semiconductor junction (or GaAs homojunction) has a forbidden energy band width of approximately 1.43 eV, the second GaInP semiconductor junction (or GaInP homojunction) has a forbidden energy band width of approximately 1.84 eV, and the GaAs/GaInP semiconductor heterojunction is thus capable of converting, into electricity, the wavelengths of the solar radiation below the forbidden energy bands of the two homojunctions.

The association of these semiconductor junctions allows an effective conversion of solar energy into electric energy in a wide spectrum, while allowing the passage of the IR rays.

In particular, the photovoltaic cell 4 lacks a Germanium (Ge) semiconductor layer, which would absorb the IR rays and is also expensive.

In a known manner, on either side of the stack of semiconductor layers 22, 24, 26, 28, the photovoltaic cell comprises electrodes 30, 32 for collecting the electric charges.

Other arrangements of semiconductor layers and semiconductor junctions can be considered.

Preferably, in order to favor the transparency of the cell to the IR rays, the semiconductor layers are thin layers. They for example have a thickness comprised between 1 and 20 μm, in particular between 1 and 10 μm. Such thin semiconductor layers are for example obtained, in a known manner, by transfer or growth by epitaxy on a substrate 34, so as to minimize dislocations or other flaws at the interface of the semiconductor layers.

Preferably, the substrate 34 is made from a material chosen for its transparency to IRs. The substrate is for example made from infrared-transparent glass.

The effectiveness of a photovoltaic cell decreases after a certain temperature, with a rate of decrease that depends on the junction(s) making it up.

In order to ensure the operation of the photovoltaic cell 4 and the heat sink 6 in satisfactory temperature ranges, the concentration factor of the concentration means concentrator of the collector 2 is preferably comprised between 80 and 120, in particular approximately equal to 100.

It will be noted that the photovoltaic cell 4 favoring the passage of IR rays makes it possible to work with high concentration factors while limiting the thermal heating of the photovoltaic cell.

As illustrated in FIG. 3, the solar power station 36 comprises a first circuit 38 for the circulation of a heat fluid and a second circuit 40 for the circulation of a working fluid, and a heat exchanger 42 between the heat fluid and the working fluid.

The heat fluid is for example a synthesis oil that can reach high temperatures, in the vicinity of 250° C. to 400° C., without evaporation. The working fluid is for example water.

The first circuit 38 comprises, in series, a pump 44 for circulation of the heat fluid and a field of solar energy collectors 2 as illustrated in FIGS. 1 and 2. The collectors 2 are arranged in parallel.

The second circuit 40 comprises, in series, a steam turbine 46 [that is driven by the working fluid in the vapor state], a condenser 48 and the circulation pump 50.

The heat exchanger 42 comprise a preheater 52, an evaporator 54, and a superheater 56, passed through in inverse order by the first circuit 38 and the second circuit 40: the first circuit 38 successively passes through the superheater 56, the evaporator 54, and the preheater 52, while the second circuit 40 successively passes through the preheater 52, the evaporator 54, and the superheater 56.

The turbine 46 is coupled to an electric generator 58.

Optionally, in a known manner, the second circuit 40 comprises one or more preheaters 60 connected to intermediate bleeds 62 of the turbine 46 and the condenser 48.

During operation, the heat fluid circulates in the first circuit 38 and is heated in the collectors, to a temperature that may reach 250° C. t o 400° C. In passing through the heat exchanger 42, it gives calories to the working fluid. The working fluid is successively preheated, evaporated, then superheated in the preheater 52, the evaporator 54, and the superheater 56.

In the steam turbine 46, the working fluid expands upon cooling and rotates the output shaft of the turbine 46. The latter is coupled to an electric generator 58 to produce electric energy.

The solar power station 36 thus makes it possible to convert the solar energy into electric energy. Part of the solar energy is converted directly into electric energy by the collectors 2, while another part of the solar energy is converted into heat energy by the collectors 2 before being converted into mechanical energy (turbine 46), then electric energy (generator 58).

The solar power station 36 provided with collectors 2 makes it possible to obtain a high output while optimizing the share of solar energy that is directly converted into electric energy by the photovoltaic cells, and that which serves to heat the heat fluid.

Other types of solar power stations can use the collectors 2. For example, in a solar power station, the heat fluid can also serve as working fluid and be used directly in a steam turbine without providing separate circuits coupled by intermediate heat exchangers.

As shown in FIGS. 4 and 5, where the references to the elements similar to those of FIG. 1 have been kept the same, the collector 2 differs from that of FIG. 1 in that it comprises photovoltaic cells 4 arranged along the heat sink 6 so that part of the solar energy reaches the heat sink 6 while being filtered by the photovoltaic cells 4, and the other part of the solar energy directly reaches the heat sink 6 through at least one opening formed between the photovoltaic cells 4.

As shown in FIGS. 4 and 5, the heat sink 6 is elongated in a direction perpendicular to the plane of FIG. 4, and the collector 2 comprises two series 64, 66 of photovoltaic cells 4 distributed along the heat sink 6. Each photovoltaic cell 4 of one series is longitudinally opposite a photovoltaic cell 4 of the other series.

The photovoltaic cells 4 of one series are transversely spaced apart from the photovoltaic cells 4 of the other series, so that the photovoltaic cells 4 define between a longitudinal opening 68 extending along the heat sink 4.

As shown in FIG. 5, photovoltaic cells 4 are spaced longitudinally apart such that transverse openings 70 are defined between the photovoltaic cells 4. The transverse openings 70 are such that in the transverse plane passing through each transverse opening 70, the entire light beam directly reaches the heat sink 6 without being filtered by the photovoltaic cells 4.

This embodiment makes it possible to have a large heat sink, in particular with a large diameter, while preserving small photovoltaic cells. This makes it possible to limit the cost of the photovoltaic cells, the price of which increases greatly with the surface.

The transverse openings 70 make it possible to allow transverse bands of the heat sink 6 to receive a complete solar flow, which can be advantageous in the heat balance of the heat sink 6, without, however, decreasing the performance of the photovoltaic cells 4.

The openings 68, 70 between the photovoltaic cells 4 improve the cooling by natural convection of the photovoltaic cells 4. However, it is known that the performance of the photovoltaic cells decreases as the temperature rises. This improved natural convection makes it possible to maintain or improve the performance of photovoltaic cells relative to a device where the photovoltaic cells are not spaced apart.

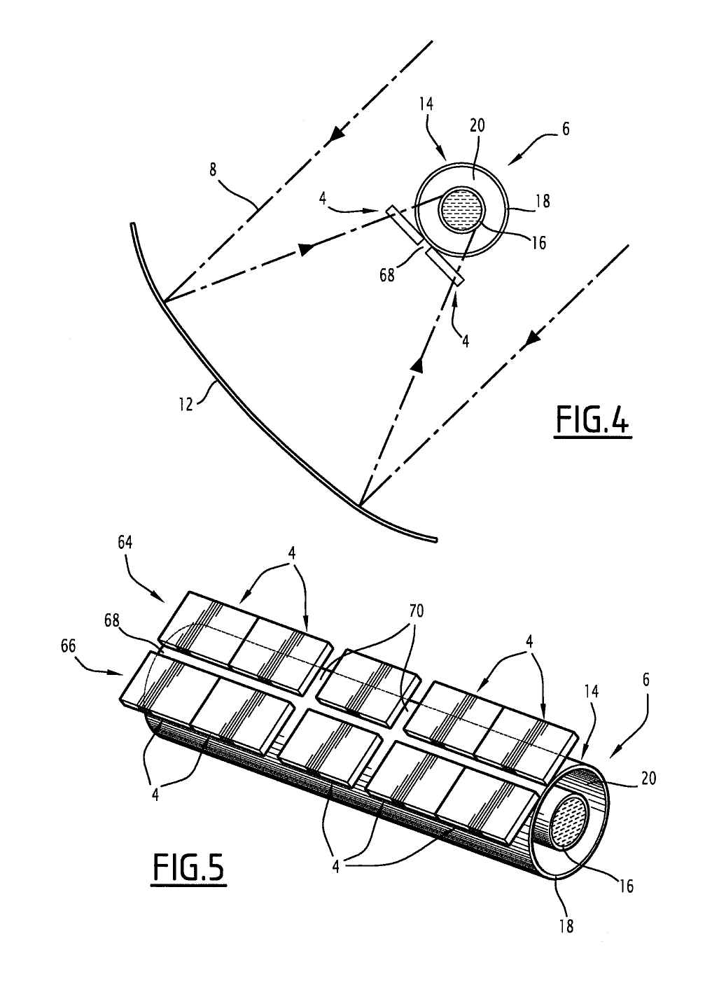

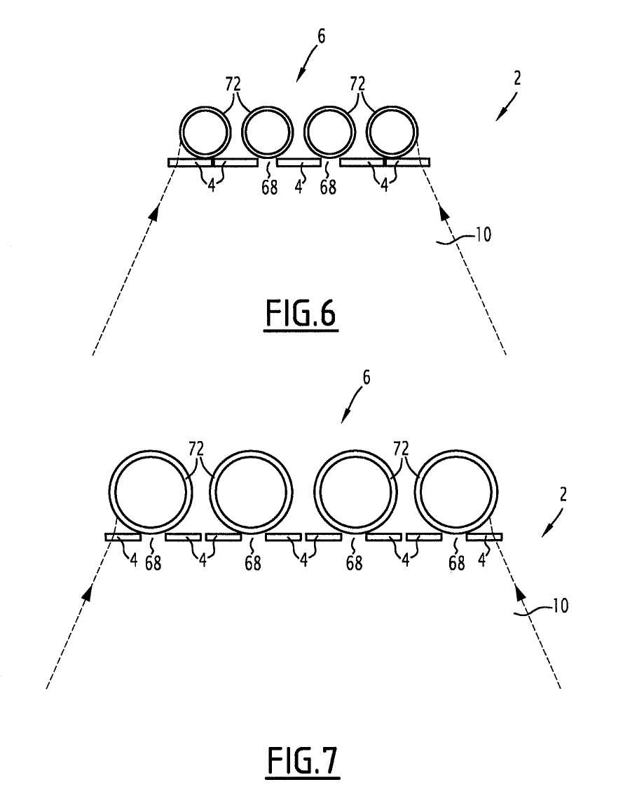

The collector 2 illustrated in FIG. 6 differs from the preceding embodiments in that the heat sink 6 comprises a bundle of parallel conduits 72.

The conduits 72 have a single wall. They are for example made from steel. Alternatively, the conduits 72 have a double wall with an intermediate vacuum.

The conduits 72 are spaced so as to receive the concentrated light beam 10 through photovoltaic cells 4 according to the invention.

The collector 2 comprises several series of photovoltaic cells 4. Each series of photovoltaic cells 4 comprises a plurality of those distributed along the conduits 72 in the direction of extension of the conduits 72 (perpendicular to the plane of FIG. 6). The series are distributed transversely to the direction of extension of the conduits 72.

Optionally, and as illustrated in FIG. 6, certain photovoltaic cells are spaced apart and define longitudinal openings 68 between them. In the illustrated example, the collector 2 comprises four parallel conduits 72 and five series of photovoltaic cells 4 transversely distributed and defining two longitudinal openings 68 between them.

The collector 2 illustrated in FIG. 7 differs from that of FIG. 6 in that it comprises, for each conduit 72, two series of photovoltaic cells 4 defining a longitudinal opening 68 between them.

The conduits also have larger diameters.

Furthermore, the invention is not limited to collectors comprising the concentrator in the form of a cylindro-parabolic mirror.

Alternatively, a collector according to the invention comprises the concentrator in the form of Fresnel mirrors. Fresnel mirror fields associated with different sinks can be interlinked to define a compact linear Fresnel reflector (CLFR).

The different types of the concentrator and sink, and arrangements of the concentrator and sinks mentioned above can be combined.

Thus, the invention applies to a power station as disclosed in WO2009/029277, comprising linear solar energy collectors combining an interlinked Fresnel mirror concentrator and heat sinks with bundles of parallel conduits.

1-15. (canceled)

15. A hybrid solar energy collector comprising:
at least one photovoltaic cell for converting solar energy into electric energy; and
at least one heat sink for converting solar energy into heat energy by heating a fluid, the at least one heat sink being arranged so as to receive the solar energy through the photovoltaic cell, the photovoltaic cell including several superimposed semiconductor junctions having different forbidden energy band widths, each semiconductor junction having a forbidden energy band equal to or greater than 1.2 eV.

16. The solar energy collector as recited in claim 15 wherein each semiconductor junction has a forbidden energy band equal to or greater than 1.4 eV.

17. The solar energy collector as recited in claim 15 wherein the photovoltaic cell includes at least one GaAs semiconductor layer.

18. The solar energy collector as recited in claim 15 wherein the photovoltaic cell includes at least one GaInP or GaInP2 semiconductor layer.

19. The solar energy collector as recited in claim 15 wherein the semiconductor junctions of the photovoltaic cell are formed by fine semiconductor layers.

20. The solar energy collector as recited in claim 19 wherein the semiconductor layers have a thickness comprised between 1 and 20 μm.

21. The solar energy collector as recited in claim 19 wherein the semiconductor layers have a thickness comprised between 1 and 10 μm.

22. The solar energy collector as recited in claim 19 wherein the semiconductor layers are formed on a substrate.

23. The solar energy collector as recited in claim 22 wherein the semiconductor layers are formed on the substrate using a transfer or epitaxy method.

24. The solar energy collector as recited in claim 22 wherein the substrate is made from a glass or an infrared-transparent ceramic.

25. The solar energy collector as recited in claim 15 further comprising a concentrator for concentrating an incident solar beam to form a concentrated solar beam oriented toward the photovoltaic cell and the heat sink.

26. The solar energy collector as recited in claim 25 wherein a concentration factor of the concentrator is between 80 and 120.

27. The solar energy collector as recited in claim 25 wherein a concentration factor of the concentrator is approximately equal to 100.

28. The solar energy collector as recited in claim 15 wherein the at least one photovoltaic cell includes several photovoltaic cells defining at least one opening therebetween so that part of the solar energy reaches the heat sink through the photovoltaic cells and part of the solar energy reaches the heat sink through the or each at least one opening.

29. The solar energy collector as recited in claim 28 wherein the heat sink is elongated and the photovoltaic cells delimit at least one longitudinal opening extending longitudinally along the heat sink, the photovoltaic cells being spaced transversely away from one another along the at least one longitudinal opening.

30. The solar energy collector as recited in claim 28 wherein the heat sink is elongated and the photovoltaic cells delimit at least one longitudinal opening extending longitudinally along the heat sink, the photovoltaic cells being spaced longitudinally away from one another along the at least one transverse opening.

31. The solar energy collector as recited in claim 15 wherein the heat sink includes a bundle of parallel conduits for channeling the fluid.

32. An electricity-producing solar power plant comprising at least one of the solar energy collector recited in claim 15.

33. The power plant as recited in claim 32 further comprising:
a first circuit for circulating a coolant, the first circuit being connected to the at least one solar energy collector;
a steam power station including at least one steam turbine;
a second circuit for circulating a working fluid, the second circuit being connected to the steam power station; and
at least one heat exchanger between the first circulation circuit and the second circulation circuit.
